(19) United States
(12) Patent Application Publication
(10) Pub. No.: US 2014/0102554 A1
(43) Pub. Date: Apr. 17, 2014

(54) AIRFLOW GUIDE MEMBER

(71) Applicant: HON HAI PRECISION INDUSTRY CO., LTD., New Taipei (TW)

(72) Inventors: HSUAN-I LIN, New Taipei (TW); CHENG-HSIU YANG, New Taipei (TW)

(73) Assignee: HON HAI PRECISION INDUSTRY CO., LTD., New Taipei (TW)

(21) Appl. No.: 13/746,254

(22) Filed: Jan. 21, 2013

(30) Foreign Application Priority Data
Oct. 17, 2012 (TW) 101138175

(51) Int. Cl. H05K 7/20

(52) U.S. Cl. CPC H05K 7/20145
USPC 137/343

(57) ABSTRACT

An airflow guide member includes an airflow guide cover and a movable plate. The airflow guide cover includes a top plate and a number of airflow guide plates extending in a fore-and-aft direction from a bottom of the top plate. Front ends of the airflow guide plates extend forward and out of a front side of the top plate. The movable plate is slidably connected to the top plate and is capable of sliding forward to cover the front ends of the airflow guide plates.

### BACKGROUND

1. Technical Field

The present disclosure relates to an airflow guide member.

2. Description of Related Art

An electronic device, such as a computer, generally includes an airflow guide cover over a heat generation component, and a fan arranged at an end of the airflow guide cover, to dissipate heat produced by the heat generation component. Generally, the fan should be connected to the airflow guide cover closely, to prevent producing a clearance between the fan and the airflow guide cover, thus preventing air of the fan from flowing out of the airflow guide cover through the clearance. However, if a hot plug fan is positioned too close to an end of an airflow guide cover, assembling and detaching the hot plug fan would be difficult, and the airflow guide cover must be detached first to gain access to the hot plug fan, which is inconvenient.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an assembled, isometric view of an exemplary embodiment of an airflow guide member.

FIG. 2 is an inverted view of FIG. 1.

FIG. 3 is an exploded, isometric view of FIG. 2.

FIG. 4 is similar to FIG. 2, but showing the airflow guide member in another state.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean “at least one.”

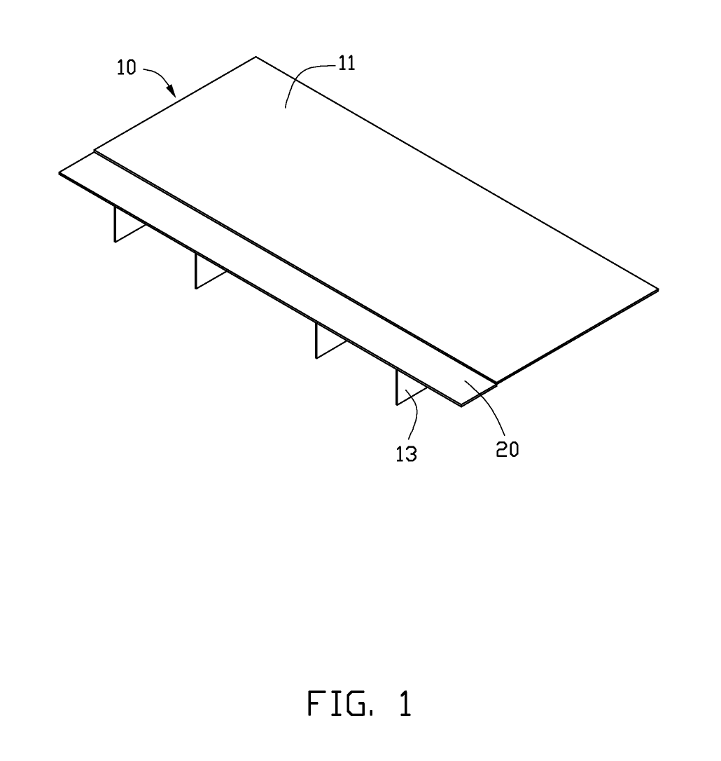

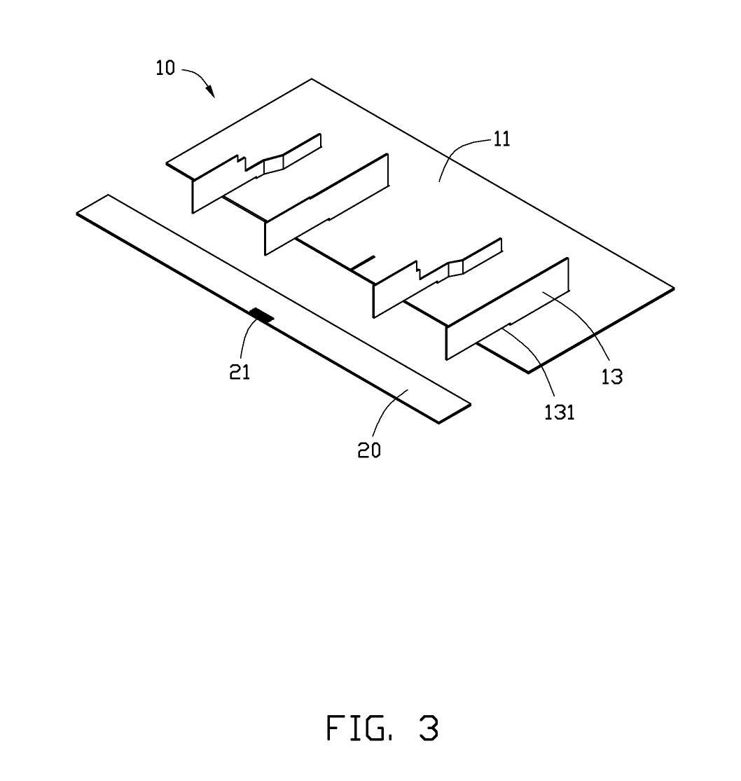

FIGS. 1 and 3 show an exemplary embodiment of an airflow guide member. The airflow guide member includes an airflow guide cover 10 and a movable plate 20.

The airflow guide cover 10 includes a top plate 11 and a plurality of airflow guide plates 13 extending in a fore-and-aft direction from the bottom of the top plate 11 in a substantially perpendicular manner. The front end of each airflow guide plate 13 extends forward and out of the front side of the top plate 11. A portion of the top of each airflow guide plate 13 adjacent to the front side of the airflow guide plate 13 is spaced from the bottom of the top plate 11, and defines a slot 131 between the top plate 11 and the airflow guide plate 13.

The movable plate 20 is substantially rectangular. A plurality of protrusions 21 is formed on the middle of the front side of the bottom of the movable plate 20, to facilitate operation of the movable plate 20.

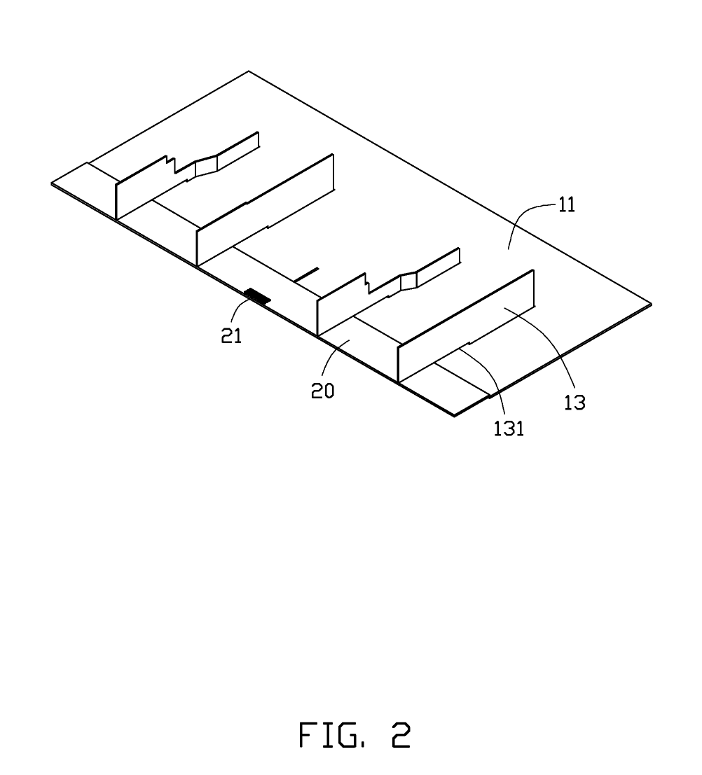

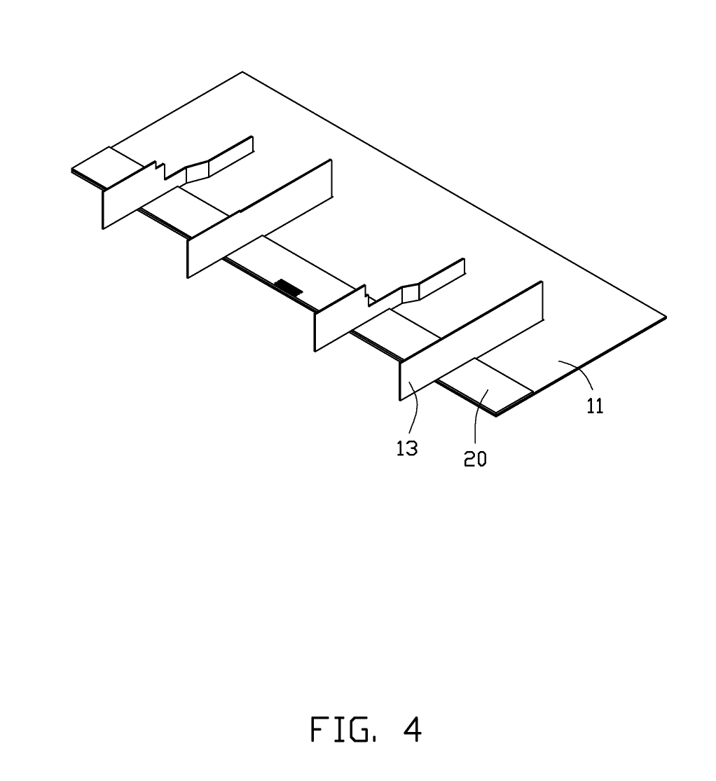

FIGS. 1, 2, and 4 show that in assembly, the rear side of the movable plate 20 is supported on the front ends of the tops of the airflow guide plates 13. The movable plate 20 is slid backward, until being completely inserted into the slots 131. Thereby, the movable plate 20 is completely sandwiched between the top plate 11 and the airflow guide plates 13.

In use, the airflow guide member is mounted in an electronic device, such as a computer, to allow the front side of the top plate 11 adjacent to the rear ends of a plurality of fans arranged in a line. The rear ends of the fans are received between the airflow guide plates 13. The movable plate 20 is slid forward, to allow the front side of the movable plate 20 to extend out of the front side of the top plate 11, to cover and be supported by the front ends of the tops of the airflow guide plates 13. The rear side of the movable plate 20 is still sandwiched between the top plate 11 and the airflow guide plates 13. The front side of the movable plate 20 covers the tops of the rear ends of the fans, to allow airflow produced by the fans to completely flow into the airflow guide cover 10, and prevent air leak.

To detach the fans, the movable plate 20 is slid backward, until the tops of the fans are completely exposed out. Thereby, the fans can be easily detached.

Even though numerous characteristics and advantages of the embodiments have been set forth in the foregoing description, together with details of the structure and the functions of the embodiments, the disclosure is illustrative only, and changes may be made in details, especially in the matters of shape, size, and arrangement of parts within the principles of the embodiments to the full extent indicated by the broad general meaning of the terms in which the appended claims are expressed.

What is claimed is:

1. An airflow guide member, comprising:
an airflow guide cover comprising a top plate and a plurality of airflow guide plates extending in a fore-and-aft direction on a bottom of the top plate, wherein front ends of the airflow guide plates extend forward and out of a front side of the top plate; and
a movable plate slidably connected to the top plate, wherein the movable plate is capable of sliding forward to cover the front ends of the airflow guide plates.

2. The airflow guide member of claim 1, wherein the movable plate is supported by the airflow guide plates, in response to the movable plate covering the front ends of the airflow guide plates.

3. The airflow guide member of claim 2, wherein a portion of the top of each airflow guide plate adjacent to the front end of the airflow guide plate is spaced from the bottom of the top plate, and defines a slot between the top plate and the airflow guide plate, a rear side of the movable plate is inserted into the slots between the top plate and the airflow guide plates, and is slidably sandwiched between the top plate and the airflow guide plates.

4. The airflow guide member of claim 1, wherein a plurality of protrusions is formed on a middle of a front side of a bottom of the movable plate.
